(19) United States
(12) Patent Application Publication
(10) Pub. No.: US 2003/0003403 A1
(43) Pub. Date: Jan. 2, 2003

(54) Method for improved line patterning by chemical diffusion

(76) Inventors: Everett Lee, Los Altos, CA (US); Susan Kao, Los Altos, CA (US)

Correspondence Address: Mark Seeley, BLAKELY, SOKOLOFF, TAYLOR & ZAFMAN, Seventh Floor, 12400 Wilshire Boulevard, Los Angeles, CA, 90025-1026, US

(21) Appl. No.: 09/948,719

(22) Filed: Sep. 7, 2001

Related U.S. Application Data
(63) Continuation-in-part of application No. 09/895,352, filed on Jun. 29, 2001.

(51) Int. Cl. G03F 7/40

(52) U.S. Cl. 430/313; 430/322; 430/330

(57) ABSTRACT

A method and articles of manufacture created from this method wherein a portion of a layer of photoresist material are irradiated to cause the creation of a chemical within that portion, and then the passage of time and/or the application of heat is used to cause the chemical to propagate to another portion of the layer of photoresist material.

### FIELD OF THE INVENTION

The present invention is related to the use of acid catalyst diffusion to achieve narrower patterns in photoresist material without altering the resolution of an exposure tool.

### ART BACKGROUND

Microelectronic device fabrication typically entails the use of photolithographic processes to create tiny patterns of interconnected regions of material as part of the process of forming components within a microelectronic device. These photolithographic processes entail the use of an exposure tool with a mask to project some form of radiation (e.g., ultraviolet light, electrons or x-rays) onto photoresist material. The mask (or alternatively, a reticle, where a step-and-repeat system is used) restricts projection of the radiation such that only desired regions of the photoresist material are irradiated in order to create a pattern.

The photoresist may be either a “positive resist” material in that the irradiated regions become soluble, allowing those regions to be subsequently removed, or a “negative resist” material in that the non-irradiated regions are subsequently removed. Typically, the pattern created by the removal of some regions of the photoresist material transfers a pattern to the underlying layer of material beneath the photoresist material by preventing those regions of the underlying material from being exposed, and thereby removed, in a subsequent processing step.

As the density of the circuitry of microelectronic devices has continued to increase, the lines and other shapes making up the components of that circuitry within a microelectronic device have needed to become smaller. Typically, this reduction in size is achieved by using exposure tools and/or masks (or reticles) capable of achieving ever finer resolution, or by making modifications to existing exposure tools and/or masks. However, this repeated improving or replacement of exposure tools and/or masks is quite expensive. A need exists to create smaller patterns without having to make such expensive equipment replacements or modifications.

Another prior art approach to achieving this reduction in size is to partially erode the photoresist material by exposing it to an oxygen plasma, a process commonly referred to as “ashing.” The eroding that occurs in ashing reduces the width of portions of photoresist material that remain after a pattern has been created, thereby providing a way to make thinner pattern lines or other smaller pattern features. However, the degree to which a pattern feature formed in photoresist material at a given location is eroded is hard to control with satisfactory precision since the degree of erosion at a given location is all too easily influenced environmental conditions at that location, including the proximity of other nearby pattern features. Also, the process of eroding that occurs also reduces the thickness of the layer of photoresist material, and this reduction of thickness is also affected by the environmental conditions at each given location such that the degree of reduction of thickness is not consistent. This reduction in thickness invites a risk of compromising the effectiveness of the photoresist material in preventing regions of material underlying the photoresist material from being exposed in a subsequent process step, which in turn, jeopardizes the ability of the photoresist to transfer a pattern to the underlying material.

### BRIEF DESCRIPTION OF THE DRAWINGS

The objects, features, and advantages of the present invention will be apparent to one skilled in the art in view of the following detailed description in which:

FIG. 1 is a diagram of one embodiment of the present invention.

FIG. 2 is a diagram of another embodiment of the present invention.

FIG. 3 is a diagram of still another embodiment of the present invention.

FIG. 4 is a flow chart of yet another embodiment of the present invention.

### DETAILED DESCRIPTION

In the following description, for purposes of explanation, numerous details are set forth in order to provide a thorough understanding of the present invention. However, it will be apparent to one skilled in the art that these specific details are not required in order to practice the present invention.

The present invention concerns improving the ability to create patterns with finer lines and/or smaller shapes in photoresist material. Specifically, the present invention concerns using temperature and/or additional time to allow additional chemical diffusion to occur within photoresist material, allowing more of it to become soluble so that more of the photoresist material can be removed in a subsequent processing step in order to create regions of photoresist material with thinner lines and/or smaller shapes. This resulting pattern of thinner lines or smaller shapes can be used to either transfer and thereby create such a pattern out of the material underlying the photoresist, or to create a pattern out of material to deposited amidst the photoresist within the voids created between the thinner lines and/or shapes of the photoresist pattern. Although the creation of such patterns is discussed as being part of a process of creating microelectronic circuitry, those skilled in the art will appreciate that the present invention is also applicable to the processes in which photolithographic techniques are used.

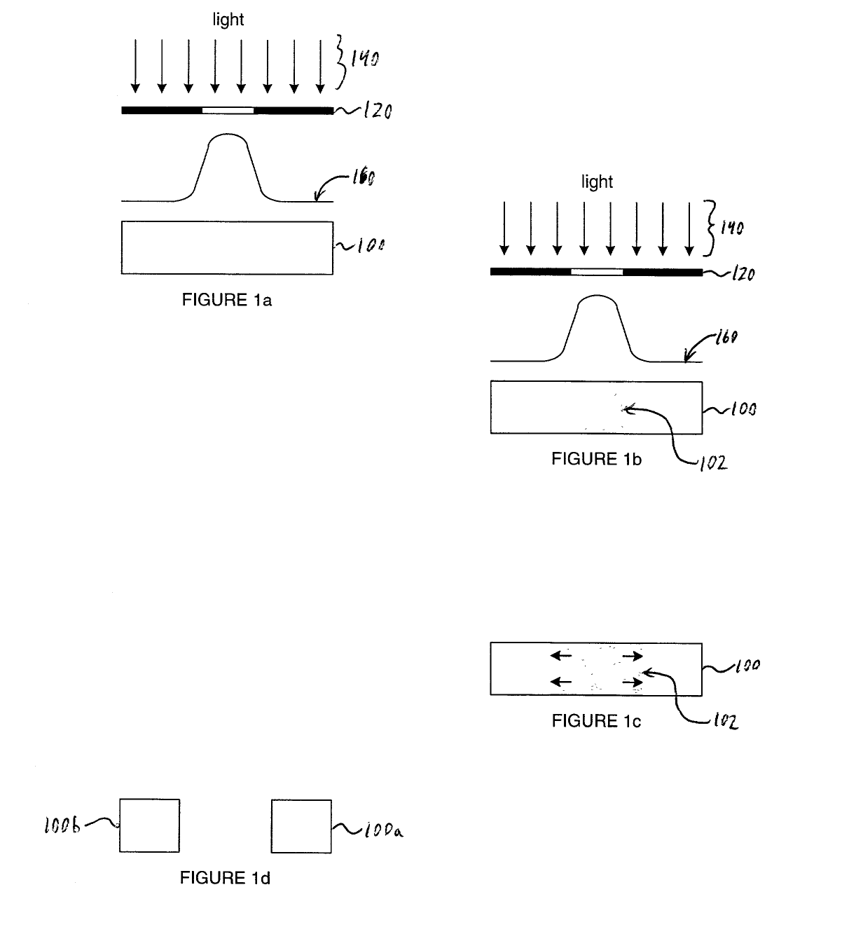

FIGS. 1a-1d depict one embodiment of the present invention. In FIG. 1a, a portion of photoresist 100 is irradiated (also commonly referred to as being “exposed”) by light 140 directed at photoresist 100 through mask 120. Mask 120 restricts the irradiation of photoresist 100 to a specific portion of photoresist 100, resulting in a pattern of differing intensity of irradiation (or “exposure”) of the kind depicted by aerial image 160. Within photoresist 100 is a photoactive compound (or “PAC”) which responds chemically to light 140 in those portions of photoresist 100 that mask 120 permits to be irradiated by light 140. In differing embodiments, light 140 maybe visible light, infrared light, ultraviolet light, x-rays, microwaves or other forms of radiant energy, whether visible to the human eye or not.

As depicted in FIG. 1b, portion 102 of photoresist 100 chemically reacts to being irradiated by light 140, resulting in portion 102 of photoresist 100 becoming chemically different from the rest of photoresist 100. In one embodiment, photoresist 100 is a positive resist and the chemical reaction that takes place as a result of being irradiated is the creation of an amount of an acid or acid catalyst. In this embodiment, this creation of acid or acid catalyst within portion 102 makes portion 102 more soluble, and therefore more susceptible to being removed by a solvent in a subsequent process step.

In FIG. 1c, portion 102 of photoresist 100 encompasses more of photoresist 100 as one or more chemical compounds created as a result of portion 102 being irradiated in FIGS. 1a and 1b diffuse into adjacent portions of photoresist 100. In one embodiment, the passage of a length of time calculated to allow this diffusion to progress to a predetermined extent before a subsequent process step is used to either chemically remove the expanded portion 102 of FIG. 1c, or to halt further diffusion while leaving the expanded portion 102 of FIG. 1c in place. In another embodiment, exposing photoresist 100 to a higher temperature calculated to allow this diffusion to progress to a predetermined extent before a subsequent process step is used. In still another embodiment, a combination of the passage of a length of time and exposure to a higher temperature is used to control the extent of this diffusion.

FIG. 1d depicts the result of the removal of the expanded portion 102 of FIG. 1c in a subsequent process step, leaving behind portions 100a and 100b of photoresist 100. In one embodiment, this diffusion and subsequent removal of expanded portion 102 is used to achieve finer dimensions for the portions 100a and 100b of photoresist 100 that are not removed in subsequent process steps. In another embodiment, this diffusion and subsequent removal of expanded portion 102 is used to reduce the amount of time an exposure tool must be used to create a given pattern within photoresist 100. In this other embodiment, an exposure tool is used to begin the process of making a portion of photoresist 100 susceptible to removal in a subsequent process step, and diffusion is used to carry the process further.

In one embodiment, FIG. 1c depicts the results of a post-exposure bake step that follows the exposure step depicted by FIGS. 1a-b and that precedes a developing step, the results of which is depicted by FIG. 1d. In common practice, the time between the completion of an exposure step and a developing step (which includes time for a post-exposure bake) is kept as short as possible to minimize opportunities for either the photoresist material 100, and/or the chemical compound or compounds created in portion 102 of FIG. 1b during exposure to react with gases in the surrounding environment. Indeed, for this reason, it is also common practice is to limit the time during which the post-exposure bake occurs to just the amount of time required to allow the chemical compound or compounds created during exposure to react with one or more materials comprising the portion of the photoresist that was irradiated (i.e., portion 102 with boundaries as defined in FIG. 1b, and not the expanded portion 102 depicted in FIG. 1c). However, in one variation of this embodiment, the post-exposure bake time is extended to allow the chemical compound or compounds created in portion 102 of FIG. 1b during exposure to diffuse into adjacent portions of photoresist material 100, resulting in the expanded portion 102 depicted in FIG. 1c. Furthermore, in this variation of this embodiment, the post-exposure bake may occur within an environment comprised of an inert gas that serves to reduce opportunities for either photoresist material 100, and/or the chemical compound or compounds created in portion 102 during exposure to react with gases in the surrounding environment during the extended post-exposure bake time.

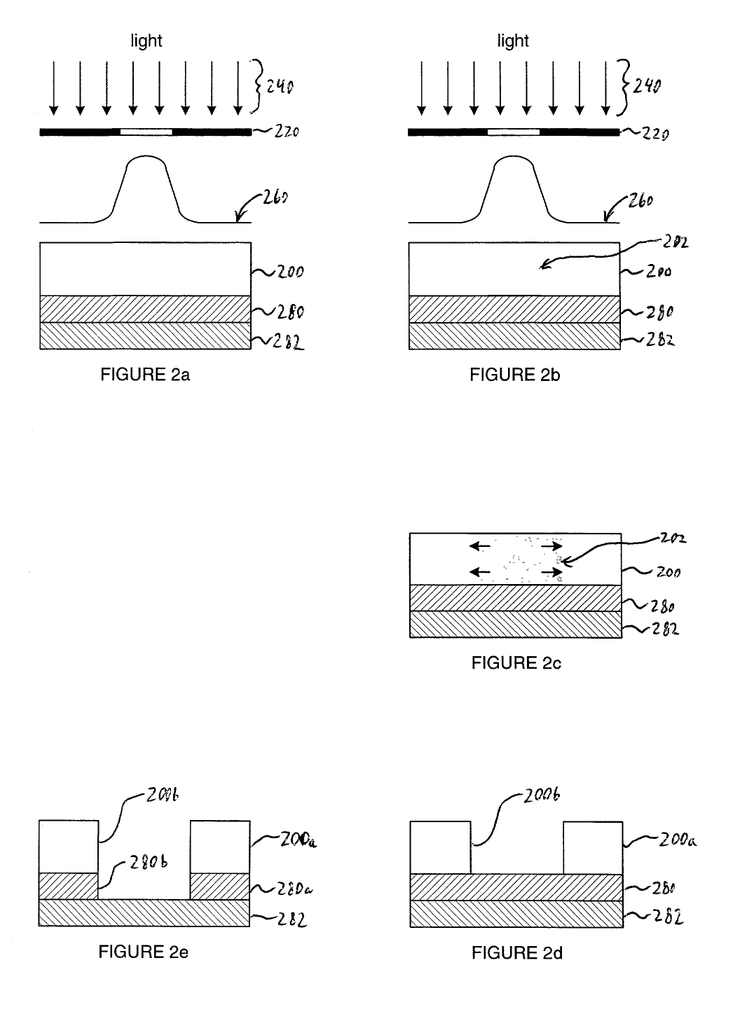

FIGS. 2a-2e depict another embodiment of the present invention as applied to the making of a pattern in a layer of material. Many of the numbered items in FIGS. 2a-2e are meant to generally correspond to numbered items in FIGS. 1a-1d. In FIG. 2a, in a manner corresponding to FIG. 1a, a portion of photoresist 200 is irradiated by light 240 directed at photoresist 200 through mask 220. Mask 220 restricts the irradiation of photoresist 200 to a specific portion of photoresist 200, resulting in a pattern of differing intensity of irradiation of the kind depicted by aerial image 260. Within photoresist 200, a photoactive compound which responds chemically to light 240 in those portions of photoresist 200 that mask 220 permits to be irradiated by light 240. However, unlike FIG. 1a, photoresist 200 is depicted as overlying two layers of material, layers 280 and 282. In one embodiment, the present invention is being used to create a microelectronic device and layer 280 is a film deposited atop a substrate in the form of layer 282.

In FIG. 2b, in a manner corresponding to FIG. 1b, portion 202 of photoresist 200 chemically reacts to being irradiated by light 240, resulting in portion 202 of photoresist 200 becoming chemically different from the rest of photoresist 200 as an amount of one or more chemicals are created within portion 202. In one embodiment, the chemical reaction that ensues causes portion 202 of photoresist 200 to become more susceptible to being removed by a solvent in a subsequent process step.

In FIG. 2c, in a manner that corresponds to FIG. 1c, portion 202 of photoresist 200 extends further into the rest of photoresist 200 as one or more of the chemicals created in the chemical reaction caused by the irradiation diffuse into adjacent portions of photoresist 200. In one embodiment, the extent to which the diffusion takes place, and therefore the extent to which portion 202 expands, is controlled by allowing a predetermined amount of time to pass before performing a subsequent step that stops the diffusion. In an alternate embodiment, the application of heat of a predetermined amount is used to either induce or increase the rate of diffusion.

In an embodiment where the extent to which diffusion takes place, and therefore the extent to portion 202 expands, is controlled by allowing a predetermined amount of time to pass, the predetermined amount of time is increased to accommodate increasing the post-exposure bake time to an amount deliberately in excess of the amount of time required to simply allow the chemical compound or compounds created in portion 202 to engage in a reaction that causes portion 202 to become more susceptible to removal in a subsequent process step. In prior art practice, the post-exposure bake time, as well as the entire time between irradiation and the subsequent process step is often minimized as much as possible to avoid unnecessarily increasing the risk of contamination of photoresist 200 and/or other the chemical compound or compounds created in portion 202, as well as to avoid unnecessarily slowing down an entire production line where post-exposure baking is carried out. The risk of contamination by reaction with one or more chemicals in the atmosphere is increased during post-exposure bake due to the addition of heat energy making photoresist 200 and/or the chemical compound or compounds created in portion 202 more reactive.

However, in one variation of this embodiment of the present invention, a longer post-exposure bake time is chosen to induce or allow diffusion to take place, with the length of the post-exposure bake time being chosen based on such factors as the characteristics of photoresist material 200, the thickness of the layer of photoresist material 200, the desired increase in the width of portion 202, the post-exposure bake temperature, the consistency of the thickness of the layer of photoresist material 200, the intensity and time of the irradiation of photoresist material 200, the depth and consistency of focus for light 240 during irradiation, steps taken to counteract inaccuracies in depth of focus for light 240, the time and temperature at which a soft bake step prior to exposure was carried out, and/or the uniformity of the temperature of the post-exposure bake throughout photoresist material 200. In this variation of this embodiment, the post-exposure bake temperature may also be controlled (in addition to the post-exposure bake time being controlled) to ensure that the width of features created in a desired pattern remain uniform despite inherent inaccuracies or variations in other factors.

In another variation of this embodiment, a commonly available photoresist material is used, and the limits specified by the manufacturer regarding post-exposure bake temperatures are adhered to. The initial recommendation for post-exposure bake time from the manufacturer (which is in the range of 60 to 90 seconds for some commonly available photoresist materials) is first tried, and then reductions and increases in that time by 5% or 10% are tried to determine the degree to which portion 202 would expand.

In still another variation of this embodiment, recommendations are made to a manufacturer of photoresist materials to either alter the chemical makeup of a commonly available photoresist material 200 or to create a new photoresist material 200 that will have characteristics that better optimize photoresist material 200 for controlling the degree of diffusion through control of the post-exposure bake time.

In yet another variation of this embodiment, photoresist material 200 is dosed with an additional chemical compound to a degree that is controlled (in addition to the post-exposure bake time being controlled) to ensure that the width of features created in a desired pattern remain uniform despite inherent inaccuracies or variations in other factors, including uniformity of temperature.

In one specific variation of this embodiment, TDUR 501, a product of Japan-based Tokyo Ohka Kogyo, is used as photoresist material 200. In this variation of this embodiment, the post-exposure bake time is increased to 120 seconds to cause the width of portion 202 to expand by at least 10 nm. Alternatively, the post-exposure bake time is increased to 150 seconds to cause the width of portion 202 to expand by at least 25 nm. In still another alternative, the post-exposure bake time is increased to beyond 150 seconds, achieving still greater expansions of portion 202.

In another specific variation of this embodiment, TDUR 534, another product of Japan-based Tokyo Ohka Kogyo, is used as photoresist material 200. In this variation of this embodiment, the post-exposure bake time is increased to 180 seconds to cause the width of portion 202 to expand by at least 15 nm. Alternatively, the post-exposure bake time is increased to 270 seconds to cause the width of portion 202 to expand by at least 25 nm. In still another alternative, the post-exposure bake time is increased to beyond 270 seconds, achieving still greater expansions of portion 202.

In an embodiment where the extent to which diffusion takes place, and therefore the extent to portion 202 expands, is controlled by the application of heat, the post-exposure bake temperature is raised to an amount deliberately in excess of the temperature required to simply allow the chemical compound or compounds created in portion 202 to engage in a reaction that causes portion 202 to become more susceptible to removal in a subsequent process step. In prior art practice, the post-exposure bake temperature is often minimized as much as possible to avoid unnecessarily increasing the risk of inducing unwanted chemical reactions in photoresist 200 and/or other the chemical compound or compounds created in portion 202, as well as to avoid unnecessarily slowing down an entire production line where post-exposure baking is carried out. As discussed earlier, the risk of a chemical reaction with one or more chemicals in the atmosphere is increased during post-exposure bake due to the addition of heat energy making photoresist 200 and/or the chemical compound or compounds created in portion 202 more reactive.

However, in one variation of this embodiment of the present invention, a higher post-exposure bake temperature is chosen to induce or allow diffusion to take place, with the choice of temperature being based on such factors as the characteristics of photoresist material 200, the thickness of the layer of photoresist material 200, the desired increase in the width of portion 202, the post-exposure bake time, the consistency of the thickness of the layer of photoresist material 200, the intensity and time of the irradiation of photoresist material 200, the depth and consistency of focus for light 240 during irradiation, steps taken to counteract inaccuracies in depth of focus for light 240, the time and temperature at which a soft bake step prior to exposure was carried out, and/or the uniformity of the temperature of the post-exposure bake throughout photoresist material 200. In this variation of this embodiment, the post-exposure bake temperature may also be controlled to ensure that the width of features created in a desired pattern remain uniform despite inherent inaccuracies or variations in other factors. Furthermore, in this variation of this embodiment, the temperature at which photoresist material 200 would be expected to liquefy may also be taken into account.

Just as in FIG. 1d, FIG. 2d depicts the result of the removal of expanded portion 202 of photoresist 200 in a subsequent process step, leaving behind portions 200a and 200b of photoresist 200. FIG. 2e then depicts the result of a later process step in which a portion of layer 280 that was no longer covered by photoresist 200 is removed, thereby transferring the pattern made in photoresist 200 through FIGS. 2a-2d to layer 280.

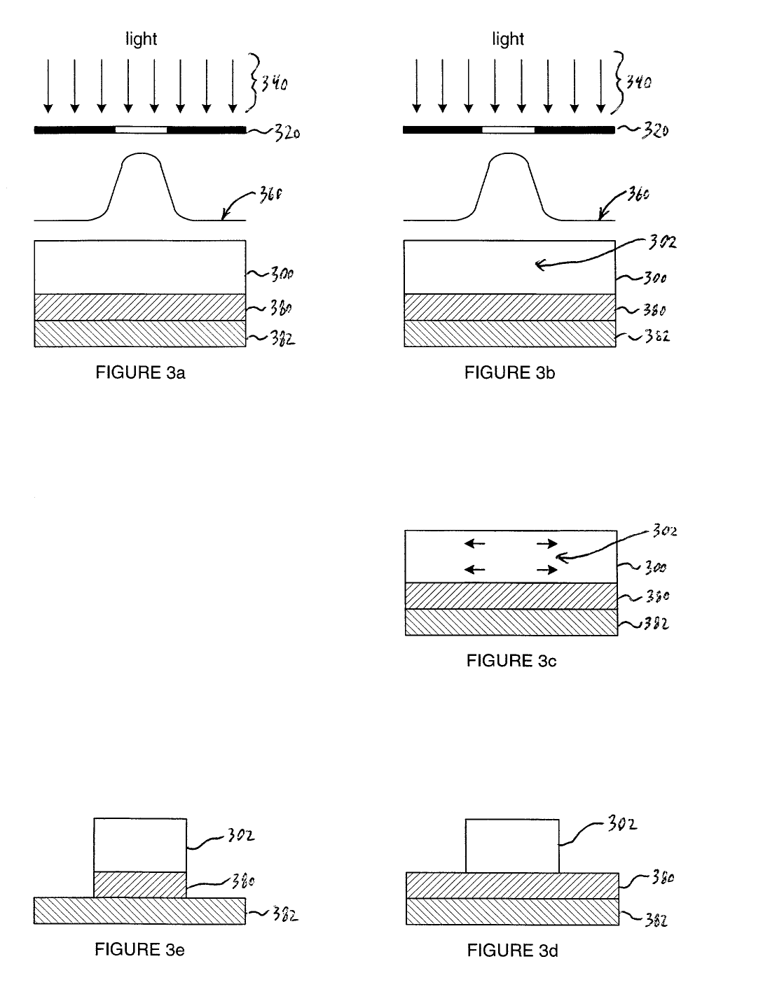

FIGS. 3a-3e depict still another embodiment of the present invention as applied to the making of a pattern in a layer of material. Many of the numbered items in FIGS. 3a-3e are meant to generally correspond to numbered items in FIGS. 2a-2e. In FIG. 3a, in a manner corresponding to FIG. 2a, a portion of photoresist 300, which overlies layers 380 and 382, is irradiated by light 340 directed at photoresist 300 through mask 320. Mask 320 restricts the irradiation of photoresist 300 to a specific portion of photoresist 300, resulting in a pattern of differing intensity of irradiation of the kind depicted by aerial image 360. Within photoresist 300, a photoactive compound responds chemically to light 340 in those portions of photoresist 300 that mask 320 permits to be irradiated by light 340.

In FIG. 3b, a manner that is somewhat analogous to FIG. 2b, portion 302 of photoresist 300 chemically reacts to being irradiated by light 340, resulting in portion 302 of photoresist 300 becoming chemically different from the rest of photoresist 300 as an amount of one or more chemicals are created within portion 302. However, unlike portion 202 of FIGS. 2a-2e, the chemical reaction occurring within portion 302 results in portion 302 becoming less susceptible, rather than more susceptible, to being removed in a subsequent process step.

In FIG. 3c, portion 302 of photoresist 300 extends further into the rest of photoresist 300 as one or more of the chemicals created in the chemical reaction caused by the irradiation diffuse into adjacent portions of photoresist 300. In one embodiment, the extent to which the diffusion takes place, and therefore the extent to which portion 302 extends further into adjacent portions of photoresist 300, is controlled by allowing a predetermined amount of time to pass before performing a subsequent step that stops the diffusion. In an alternate embodiment, the application of heat of a predetermined amount is used to either induce or increase the rate of diffusion.

In one embodiment, one of the chemicals created in the chemical reaction resulting from portion 302 of photoresist 300 being exposed to light 340 is an acid or acid catalyst. In this embodiment, it is this acid or acid catalyst that diffuses into the portions of photoresist 300 that are adjacent to portion 302, thereby extending portion 302. In a subsequent step in this embodiment, photoresist 300 is exposed to a vapor containing a chemical compound that diffuses into photoresist 300, including portion 302, and reacts with the acid or acid catalyst with the result that portion 302 of photoresist 300 becomes less susceptible to being removed in a subsequent process step than adjacent portions of photoresist 300. In an alternate embodiment, photoresist 300 is doped with a material that allows the acid or acid catalyst to be later altered to again make portion 302 less susceptible to being removed in a subsequent process step.

FIG. 3d depicts the result of the removal of the portions of photoresist 300 that were adjacent to portion 302, leaving behind portion 302. FIG. 3e then depicts the result of a later process step in which portions of layer 380 that was no longer covered by photoresist 300 are removed, thereby transferring the pattern made in photoresist 300 through FIGS. 3a-3d to layer 380.

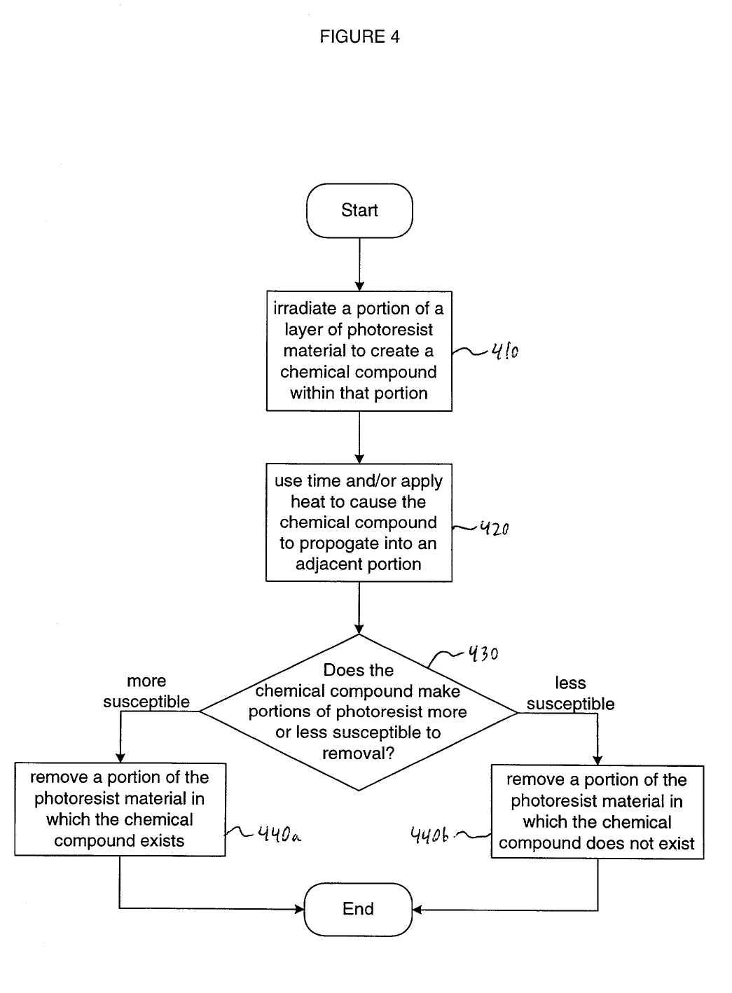

FIG. 4 depicts yet another embodiment of the present invention in the form of a flow chart. At 410, a portion of a layer photoresist material is irradiated, causing chemical reaction to occur within that portion, resulting in the formation of a chemical compound within that portion. In one variation of this embodiment, there would be multiple portions of a layer of photoresist material that would be irradiated, and other multiple portions that would not be, forming a pattern. At 420, the passage of time and/or the application of heat is used to cause the chemical compound formed at 410 to propagate into an adjacent portion of the layer of photoresist that had not been irradiated at 410.

If at 430, the effect of the chemical compound on a portion of photoresist material is to make that portion more susceptible to being removed in a subsequent process step, then at 440a, a portion of the photoresist material in which the chemical compound exists is removed in a subsequent process step. However, if at 430, the effect of the chemical compound on a portion of photoresist material is to make that portion less susceptible to being removed in a subsequent process step, then at 440b, a portion of the photoresist material in which the chemical compound does not exist is removed by a subsequent process step.

The invention has been described in conjunction with the preferred embodiment. It is evident that numerous alternatives, modifications, variations and uses will be apparent to those skilled in the art in light of the foregoing description. It will be understood by those skilled in the art that the present invention may be practiced in support of the manufacture of various articles other than microelectronic devices in which photolithographic techniques are used. It will also be understood by those skilled in the art that the present invention may be practiced in support of processes other than manufacturing such as prototyping or process verification.

The example embodiments of the present invention are described in the context of the manufacture of microelectronic devices using a light source directed at a microelectronic device being manufactured through a mask. However, the present invention is applicable to other forms of controlled exposure to or projection of various types of radiant energy, including lasers and other devices capable of controlling the size or configuration of the exposure, with or without the use of a mask or reticle.

What is claimed is:

1. A method, comprising:
irradiating a first portion of a layer of photoresist material to create at least one chemical within the first portion;
increasing the amount of time during which the photoresist material is baked after the first portion was irradiated beyond the amount of time necessary for the at least one chemical to react with the photoresist material of the first portion to also allow the chemical to both propagate into a second portion of the layer of photoresist material that is adjacent to the first portion and to chemically react with the photoresist material of the second portion.

2. The method of claim 1, further comprising:
if the chemical makes a portion of the photoresist material more susceptible to removal in a subsequent step, then remove portions of the photoresist material in which the chemical exists, while not removing portions of the photoresist material in which the chemical does not exist; and
if the chemical makes a portion of the photoresist material less susceptible to removal in a subsequent step, then remove portions of the photoresist material in which the chemical does not exist, while not removing portions of the photoresist material in which the chemical exists.

3. The method of claim 2, wherein the chemical created by irradiating the first portion is an acid catalyst capable of making a portion of photoresist material more susceptible to removal by a solvent in a subsequent step.

4. The method of claim 2, wherein the removal of some portions of photoresist material forms a pattern comprised of the portions of the photoresist material that are not removed.

5. The method of claim 4, wherein the formed pattern is used to transfer a pattern to a layer of material comprising a microelectronic device.

6. A method, comprising:
irradiating a first portion of a layer of photoresist material to create at least one chemical within the first portion; and
increasing the amount of heat used in baking the photoresist material after the first portion was irradiated beyond the temperature necessary for the at least one chemical to react with the photoresist material of the first portion to also allow the chemical to both propagate into a second portion of the layer of photoresist material that is adjacent to the first portion and to chemically react with the photoresist material of the second portion.

7. The method of claim 6, further comprising:
if the chemical makes a portion of the photoresist material more susceptible to removal in a subsequent step, then remove portions of the photoresist material in which the chemical exists, while not removing portions of the photoresist material in which the chemical does not exist; and
if the chemical makes a portion of the photoresist material less susceptible to removal in a subsequent step, then remove portions of the photoresist material in which the chemical does not exist, while not removing portions of the photoresist material in which the chemical exists.

8. The method of claim 7, wherein the chemical created by irradiating the first portion is an acid catalyst that makes a portion of photoresist material more susceptible to removal by a solvent in a subsequent step.

9. The method of claim 7, wherein the removal of some portions of photoresist material forms a pattern comprised of the portions of the photoresist material that are not removed.

10. The method of claim 9, wherein the formed pattern is used to transfer a pattern to a layer of material comprising a microelectronic device.

11. An article of manufacture created by:
irradiating a first portion of a layer of photoresist material to create at least one chemical within the first portion;
increasing the amount of time during which the photoresist material is baked after the first portion was irradiated beyond the amount of time necessary for the at least one chemical to react with the photoresist material of the first portion to also allow the chemical to both propagate into a second portion of the layer of photoresist material that is adjacent to the first portion and to chemically react with the photoresist material of the second portion.

12. The article of manufacture of claim 11, further created by:
if the chemical makes a portion of the photoresist material more susceptible to removal in a subsequent step, then remove portions of the photoresist material in which the chemical exists, while not removing portions of the photoresist material in which the chemical does not exist; and
if the chemical makes a portion of the photoresist material less susceptible to removal in a subsequent step, then remove portions of the photoresist material in which the chemical does not exist, while not removing portions of the photoresist material in which the chemical exists.

13. The article of manufacture of claim 12, wherein the chemical created by irradiating the first portion is an acid catalyst that makes a portion of photoresist material more susceptible to removal by a solvent in a subsequent step.

14. The article of manufacture of claim 12, wherein the removal of some portions of photoresist material forms a pattern comprised of the portions of the photoresist material that are not removed.

15. The article of manufacture of claim 14, wherein the article of manufacture is a microelectronic device and the formed pattern is used to transfer a pattern to a layer of material comprising the microelectronic device.

16. An article of manufacture created by:
irradiating a first portion of a layer of photoresist material to create at least one chemical within the first portion;
increasing the amount of heat used in baking the photoresist material after the first portion was irradiated beyond the temperature necessary for the at least one chemical to react with the photoresist material of the first portion to also allow the chemical to both propagate into a second portion of the layer of photoresist material that is adjacent to the first portion and to chemically react with the photoresist material of the second portion.

17. The article of manufacture of claim 16, further created by:
if the chemical makes a portion of the photoresist material more susceptible to removal in a subsequent step, then remove portions of the photoresist material in which the chemical exists, while not removing portions of the photoresist material in which the chemical does not exist; and
if the chemical makes a portion of the photoresist material less susceptible to removal in a subsequent step, then remove portions of the photoresist material in which the chemical does not exist, while not removing portions of the photoresist material in which the chemical exists.

18. The article of manufacture of claim 17, wherein the chemical created by irradiating the first portion is an acid catalyst that makes a portion of photoresist material more susceptible to removal by a solvent in a subsequent step.

19. The article of manufacture of claim 17, wherein the removal of some portions of photoresist material forms a pattern comprised of the portions of the photoresist material that are not removed.

20. The article of manufacture of claim 19, wherein the article of manufacture is a microelectronic device and the formed pattern is used to transfer a pattern to a layer of material comprising the microelectronic device.
